(19) United States
(12) Patent Application Publication
(10) Pub. No.: US 2018/0146546 A1
(43) Pub. Date: May 24, 2018

(54) Single-Layer Combined Power, Intelligence, And Communications Capable Modular Integrated Stackable Layer Module

(71) Applicant: Matthew J Leonard, College Station, TX (US)

(72) Inventor: Matthew J Leonard, College Station, TX (US)

(21) Appl. No.: 15/497,047

(22) Filed: Apr. 25, 2017

Related U.S. Application Data
(63) Continuation-in-part of application No. 15/363,642, filed on Nov. 29, 2016.
Application No. 15/363,642 is a continuation-in-part of application No. 15/360,797, filed on Nov. 23, 2016.

(51) Int. Cl. H05K 1/02; H05K 1/18

(52) U.S. Cl. CPC H05K 1/0298; H05K 1/18

(57) ABSTRACT

A single-layer combined power, intelligence, and communications capable modular integrated stackable layer (MISL) combines the functionalities of power management, intelligence, and communications into a single flattened MISL layer in order to reduce the physical volume occupied by a MISL stack.

### FIELD OF THE INVENTION

The present invention relates generally to microcontroller applications. More particularly, the present invention relates to modular, scalable and reconfigurable microcontroller applications.

### BACKGROUND OF THE INVENTION

The Modular Integrated Stackable Layer (MISL) System was conceived, architected, designed, and developed by NASA's Command and Data Handling Branch located at Johnson Space Center in Houston, Tex. The system was originally developed to decrease the cost and time to market for internal projects of the branch. Its open source deployment pathway and future design development is a partnership with Texas A&M University's Electronic Systems Engineering Technology (ESET) Program. MISL is a modular, scalable & reconfigurable system designed to support many small-scale controls, sensory, and instrumentation projects. MISL has been used for several NASA in-house projects that supported International Space Station, Orion, and Advanced Exploration System programs. The architecture provides space-qualified, rack-and-stack layers that allow embedded systems developers to quickly create the hardware platform that meets the specific requirements of the project.

In the MISL system, a given functionality is typically provided on a single “layer” or electronics module. Multiple MISL layers can be combined into a single MISL stack in order to customize the desired features of the MISL stack for a desired application. A MISL stack can become tall when combining multiple functionalities, which can present difficulties in applications where storage space is at a premium. It is therefore an object of the present invention to provide a MISL layer which integrates and combines multiple functionalities into a single layer in order to reduce the physical space a MISL stack occupies for such space-limited applications.

### BRIEF DESCRIPTION OF THE DRAWINGS

FIG. 1 is an overall diagram of the present invention.

FIG. 2 is a diagram illustrating the various electronics modules of the present invention.

FIG. 3 is a chart further detailing specific variations of the electronics modules.

### DETAIL DESCRIPTIONS OF THE INVENTION

All illustrations of the drawings are for the purpose of describing selected versions of the present invention and are not intended to limit the scope of the present invention. The present invention is to be described in detail and is provided in a manner that establishes a thorough understanding of the present invention. There may be aspects of the present invention that may be practiced without the implementation of some features as they are described. It should be understood that some details have not been described in detail in order to not unnecessarily obscure focus of the invention.

The present invention is an electronics circuit board intended for use with small microcontroller applications that work in a system that is modular, scalable and reconfigurable. More particularly, the present invention is designed specifically for use with the Modular Integrated Stackable Layers (MISL) system developed by NASA. The MISL stack system provides the ability to quickly prototype designs that are rich in features. MISL utilizes a plurality of interchangeable circuit board “layers” which can be connected to each other in a stacked configuration. The goal of the present invention is to present a single MISL layer with multiple functionalities, whereas currently a given functionality is restricted to a single MISL layer. In order to combine functionalities, multiple MISL layers must be utilized, resulting in greater occupied physical space. By combining multiple functionalities into a single layer, the present invention reduces the physical footprint of the device, enabling more efficient usage of space in devices where available space is a concern. For example, miniaturized satellites utilized for space research and other applications may have severe volume and weight restrictions in their specifications. Reducing the storage volume of a MISL stack utilized in such satellites is greatly desirable. The present invention recognizes that in certain applications, three specific capabilities are generally always required for functionality. These capabilities are: power, intelligence, and communication. Currently, these capabilities are presented only as individual MISL layers, requiring any MISL stack device to have three separate MISL layers to achieve said capabilities. The present invention combines the power, intelligence and communication into a single MISL layer in order to reduce the storage volume required. One specific application the present invention is intended for use with is a type of miniaturized satellite knows as a CubeSat. The CubeSat is utilized for space research and often put in orbit by deployers on the international space station or launched as secondary payload on a launch vehicle. Generally, the CubeSat is made of multiples of 10×10×11.35 centimeter cubic units and have a mass of no more than 1.33 kilograms per unit. Due to the compact size and the deploying cost, the CubeSat generally requires to meet the aforementioned dimensions. The present invention seeks to provide a MISL application specifically for use in CubeSat applications.

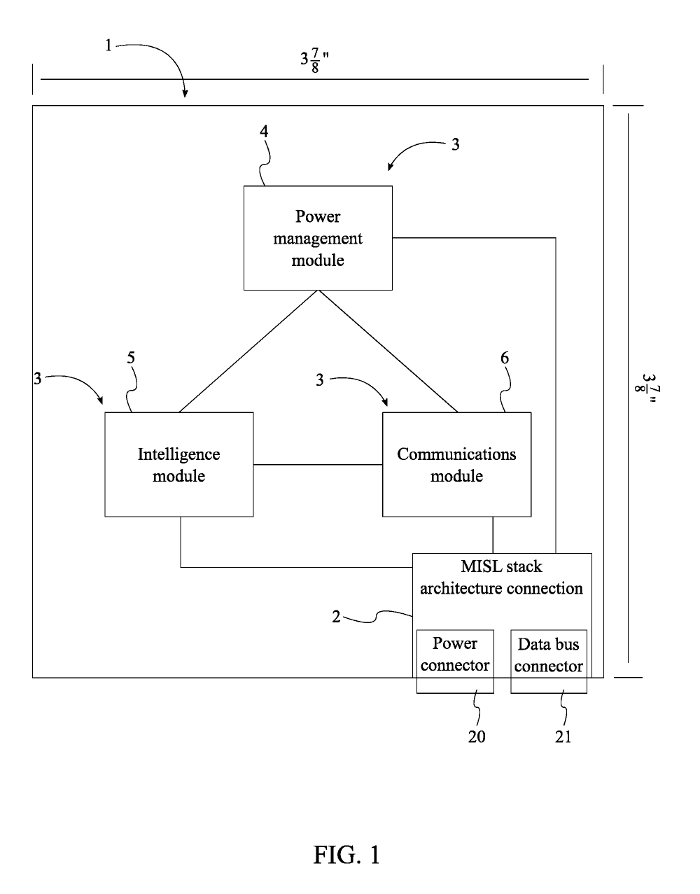

Referring to FIG. 1, the preferred embodiment of the present invention comprises a circuit board 1 configured with MISL architecture and a plurality of electronics modules 3. The circuit board 1 comprises a MISL stack architecture connection 2. In order to conform to CubeSat specifications, in the preferred embodiment the circuit board 1 has a width of 3 and ⅞ inches and a length of 3 and ⅞ inches.

In the preferred embodiment, the plurality of electronics modules 3 comprises a power management module 4, an intelligence module 5, and a communications module 6. The power management module 4, the intelligence module 5, and the communications module 6 are integrated into the circuit board 1. Furthermore, the power management module 4, the intelligence module 5, and the communications module 6 are electronically connected to each other and to the MISL stack architecture connection 2. The MISL stack architecture connection 2 comprises a power connector 20 and a data bus connector 21. The power connector 20 and the data bus connector 21 are configured according to MISL specifications so that additional MISL layers can be combined with the present invention.

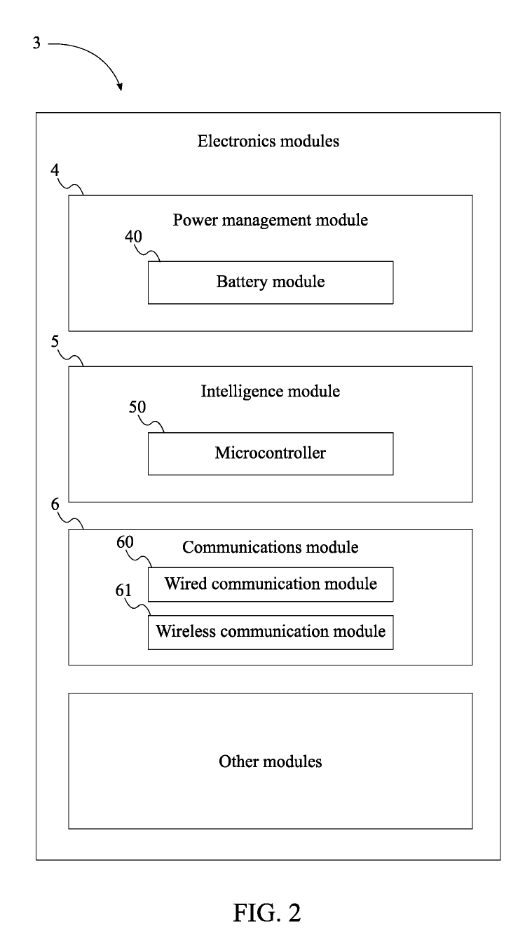

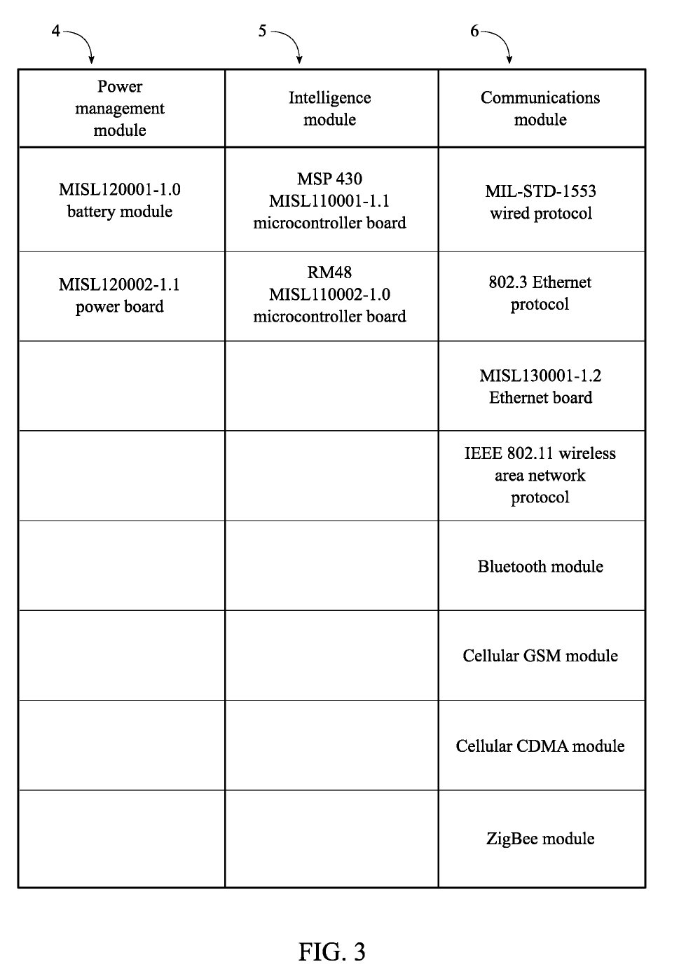

Referring to FIGS. 2-3, in the preferred embodiment of the present invention, the power management module 4 comprises a battery module 40. More specifically, in one embodiment the power management module 4 comprises a MISL120001-1.0 battery module. The MISL120001-1.0 battery module takes as input either a 5-volt input voltage from a wall adapter or two AA batteries, and produces as output regulated 3.0V at 400 mA, regulated 3.3V at 400 mA, and unregulated 5V when the 5V input is connected. In another embodiment, the power management module 4 comprises a MISL120002-1.1 24V power board. The MISL120002-1.1 24V power board can receive as input a range of 9-32V DC, and produce as output regulated 3.0V at 600 mA, regulated 3.3V at 600 mA, regulated 5V at 1.5 A, and regulated 24V at 600mA available on the power bus.

The intelligence module 5 provides data processing capabilities. In the preferred embodiment, the intelligence module 5 comprises a microcontroller 50. In general, it should be understood that the intelligence module 5 may comprise any relevant or desired combination of electronic components such as, but not limited to, integrated circuits, data processing modules, or other components that facilitate input and output of data and data processing logic through computer-executable instructions. However, it is desirable to utilize currently available MISL-related components. In one embodiment, the intelligence module 5 comprises an MSP 430, MISL110001-1.1 microcontroller board. The MSP430 is TI's MSP430F5438A microcontroller, has an on board microSD card slot, a 100 pin data bus connector to GPIO, SPI, I2C, UART, and ADC connections, and is radiation tolerant. In one embodiment, the intelligence module 5 comprises an RM48, MISL110002-1.0 microcontroller board. The RM48 board is designed with TI's RM48L952 microcontroller, has an on board Ethernet interface, USB interface, RS232/RS422/RS485 interface, microSD slot, a 100 pin data bus connector, is radiation tolerant.

The communications module 6 enables the present invention to engage in electronic communication for the purposes of control, data transfer, and any other desired purpose. In one preferred embodiment of the present invention, the communications module 6 comprises a wired communication module 60. The wired communication module 60 preferably utilizes either a MIL-STD-1553 wired protocol, an 802.3 Ethernet protocol, or both, or additional communications protocols. In one embodiment, the wired communication module 60 is a MISL130001-1.2 Ethernet board. Said Ethernet board is designed with WizNet's W5200 Ethernet controller, has an interface to a microcontroller board via SPA, has 10/100 based-T, available UDP, TCP/IP protocols, available RS232/RS422/RS485 interface, and is radiation tolerant.

In one embodiment, the communications module 6 is a wireless communication module 61. It should be understood that any wireless communication module that fits the purpose and scope of the present invention may be utilized. In one embodiment, the wireless communication module 61 utilizes the IEEE 802.11 wireless area network communication protocol. In one embodiment, the wireless communication module 61 is a Bluetooth module. In one embodiment, the wireless communication module 61 is a cellular GSM module. In one embodiment, the wireless communication module 61 is a cellular CDMA module. In one embodiment, the wireless communication module 61 is an IEEE 802.15.4 ZigBee module.

Thus, as disclosed, the present invention combines the power, intelligence, and communication functionalities of a MISL system into a single power, intelligence and communications (PIC) layer in order to reduce the physical volume occupied by a MISL stack. Although the invention has been explained in relation to its preferred embodiment, it is to be understood that many other possible modifications and variations can be made without departing from the spirit and scope of the invention as hereinafter claimed.

What is claimed is:

1. A single-layer combined power, intelligence, and communications capable modular integrated stackable layer module comprises:
a circuit board configured with modular integrated stackable layer (MISL) architecture;
the circuit board comprises a MISL stack architecture connection;
a plurality of electronics modules;
the plurality of electronics modules comprises a power management module, an intelligence module, and a communications module;
the power management module, the intelligence module, and the communications module being integrated into the circuit board; and
the power management module, the intelligence module, and the communications module being electronically connected to each other and to the MISL stack architecture connection.

2. The single-layer combined power, intelligence, and communications capable modular integrated stackable layer module as claimed in claim 1 comprises:
the circuit board having a width of 3 and ⅞ths inches and a length of 3 and ⅞ths inches.

3. The single-layer combined power, intelligence, and communications capable modular integrated stackable layer module as claimed in claim 1 comprises:
the MISL stack architecture connection comprises a power connector and a data bus connector.

4. The single-layer combined power, intelligence, and communications capable modular integrated stackable layer module as claimed in claim 1 comprises:
the power management module comprises a battery module.

5. The single-layer combined power, intelligence, and communications capable modular integrated stackable layer module as claimed in claim 1 comprises:
the intelligence module comprises a microcontroller.

6. The single-layer combined power, intelligence, and communications capable modular integrated stackable layer module as claimed in claim 1 comprises:
the communications module comprises a wired communication module.

7. The single-layer combined power, intelligence, and communications capable modular integrated stackable layer module as claimed in claim 1 comprises:
the communications module comprises a wireless communication module.
